(19) United States
(12) Patent Application Publication
(10) Pub. No.: US 2026/0219647 A1
(43) Pub. Date: Jul. 30, 2026

(54) CHARACTERIZATION OF LITHOGRAPHIC PROCESS VARIATION FOR MANUFACTURING PROCESS CALIBRATION USING IMPORTANCE SAMPLING

(71) Applicant: Siemens Industry Software Inc., Plano, TX (US)

(72) Inventors: Zexin Pan, Stanford, CA (US); Azat Latypov, San Jose, CA (US); Germain Louis Fenger, Gladstone, OR (US); Chih-I Wei, Leuven (BE)

(73) Assignee: Siemens Industry Software Inc., Plano, TX (US)

(21) Appl. No.: 19/145,221

(22) PCT Filed: Feb. 28, 2023
(86) PCT No.: PCT/US2023/014092

§ 371 Date: Jul. 2, 2025

(51) Int. Cl. G05B 19/4093; G03F 1/70; G03F 7/00

(52) U.S. Cl. CPC G05B 19/40931; G03F 1/70; G03F 7/705; G03F 7/70625; G03F 7/706837

(57) ABSTRACT

A computing system can characterize stochastic variation in a lithographic process for manufacturing an integrated circuit using importance sampling. The computing system can select a modification to the lithographic process, and identify structures of the integrated circuit that, when manufactured using the modified lithographic process, correspond to manufacturing failures. The computing system can determine a likelihood ratio based on the modification to the lithographic process relative the unmodified lithographic process for manufacturing the integrated circuit, and utilize the likelihood ratio to weigh the manufacturing failures of the structures manufactured using the modified lithographic process to characterize the stochastic variation in the unmodified lithographic process. The computing system can utilize the characterization of the stochastic variation in the unmodified lithographic process to calibrate an electronic design automation tool configured to modify a layout design for the integrated circuit or a mask design for manufacturing of the integrated circuit.

### TECHNICAL FIELD

This application is generally related to electronic design automation and, more specifically, to characterization of lithographic process variation for manufacturing process calibration.

### BACKGROUND

In a design flow for fabricating integrated circuits, a physical design of an integrated circuit can describe specific geometric elements, often referred to as a layout design. The geometric elements, which typically are polygons, define the shapes that will be created in various materials to manufacture the integrated circuit. Typically, a designer will select groups of geometric elements representing circuit device components, e.g., contacts, gates, etc., and place them in a design area. These groups of geometric elements may be custom designed, selected from a library of previously-created designs, or some combination of both. Once the groups of geometric elements representing circuit device components have been placed, geometric elements representing connection lines then are then placed between these geometric elements according to the predetermined route. These lines will form the wiring used to interconnect the electronic devices.

Descriptions for physical designs of integrated circuits can be provided in many different formats. The Graphic Data System II (GDSII) format is a popular format for transferring and archiving two-dimensional (2D) graphical circuit layout data. Among other features, it includes a hierarchy of structures, each structure having layout elements (e.g., polygons, paths or poly-lines, circles and textboxes). Other formats include an open source format named Open Access, Milkyway, EDDM, and Open Artwork System Interchange Standard (OASIS). These various industry formats are used to define the geometrical information in layout designs that are employed to manufacture integrated circuits. Once the design is finalized, the layout portion of the design can be used by fabrication tools to manufacture the circuit using a photolithographic process.

There are many different fabrication processes for manufacturing a circuit, but most processes include a series of steps that deposit photoresist on a substrate, expose specific resist-coated portions of each layer to radiation, develop the photoresist, resulting in a removal of its' exposed (or non-exposed) portions. Following the exposure and development of photoresist, the portions of the substrate exposed through the developed openings in the photoresist can be subject to further processing including the steps of etching of the exposed substrate and/or material deposition into the openings in the developed resist. For example, lithography is a process used to manufacture electronic circuits in which light is used to transfer a geometric pattern from a photomask, based on the layout design, to a silicon substrate coated by a photo-sensitive resist material, often called photoresist. One common family of photoresists is composed of entangled polymer chains. The polymer may include certain functional groups that become modified due to chemical reactions caused by exposure to light, often called deprotection, and hence affects the polymer's solubility during development, thus creating a mask for the subsequent etching process. Various types of lithographical circuit fabrication processes are possible today, including deep ultraviolet (DUV) lithography or extreme ultraviolet (EUV) lithography. In DUV or EUV lithography, stochastic phenomena may manifest during fabrication processes, such as line edge roughness or critical dimension (CD) non-uniformity.

Stochastic effects may refer to random events or effects during fabrication that occur by chance in lithographical processes. Stochastic effects can cause pattern roughness or unintended characteristics in manufactured integrated circuits (ICs). Different stochastic effects in lithographical fabrication processes can impact IC manufacture differently. Examples of stochastic effects include line-edge roughness, sidelobe printing, sub-resolution assist feature (SRAF) printability, and others. In more extreme cases, stochastic effects may lead to circuit defects, for example, stochastic pinching or bridging of the patterned features, resulting in potential failure of the electronic circuit's fabrication process. Other examples of stochastic-induced defects that can occur due to stochastic effects include ling breaks, missing contacts, also referred to as vias, kissing vias, that is merged neighboring vias, and more. Since these stochastic effects can lead to pattern or manufactured structure failure, many designers develop stochastic metrics to quantify stochastic metrics or a failure rate corresponding to the variation associated with the stochastic effects. When a probability of a pattern failure becomes small, for example, 1 failure in 10 billion exposures of a certain pattern, the ability to develop a failure rate or stochastic metric through either simulation or experimental measurements becomes increasingly expensive in time and resource consumption to render it impractical.

### SUMMARY

This application discloses a computing system implementing a lithographic process variation characterization tool to characterize stochastic variation in a lithographic process for manufacturing an integrated circuit using importance sampling. The computing system can select a modification to the lithographic process for manufacturing, and identify structures of the integrated circuit that, when manufactured using the modified lithographic process, correspond to manufacturing failures. In some embodiments, the computing system can identify structures that correspond to manufacturing failures by simulating the manufacturing process of the integrated circuit using the modified lithographic process. The computing system also can identify structures that correspond to manufacturing failures by measuring physical dimensions of structures having been manufactured using the modified lithographic process, and comparing the measured physical dimensions of the structures to predetermine thresholds to identify the structures of the integrated circuit that correspond to manufacturing failures.

The computing system can determine a likelihood ratio based, at least in part, on the modification to the lithographic process relative an unmodified lithographic process for manufacturing the integrated circuit, and utilize the likelihood ratio to weigh the manufacturing failures of the identified structures manufactured using the modified lithographic process to characterize the stochastic variation in the unmodified lithographic process for manufacturing the integrated circuit. The computing system can utilize the characterization of the stochastic variation in the unmodified lithographic process to calibrate an electronic design automation tool configured to modify a layout design for the integrated circuit or a mask design for manufacturing of the integrated circuit. Embodiments will be described below in greater detail.

### DESCRIPTION OF THE DRAWINGS

FIGS. 1 and 2 illustrate an example of a computer system of the type that may be used to implement various embodiments.

FIG. 3 illustrates an example electronic design automation system with a lithographic process variation system for stochastic variation characterization that may be implemented according to various embodiments.

FIG. 4 illustrates an example flowchart for stochastic variation characterization using importance sampling techniques that may be implemented according to various embodiments.

FIG. 5 illustrates an example flowchart for identifying integrated circuit structure failures through simulation that may be implemented according to various embodiments.

FIG. 6 illustrate examples of identifying integrated circuit structure failures through image analysis of manufactured integrated circuit structures according to various examples.

### DETAILED DESCRIPTION

### Illustrative Operating Environment

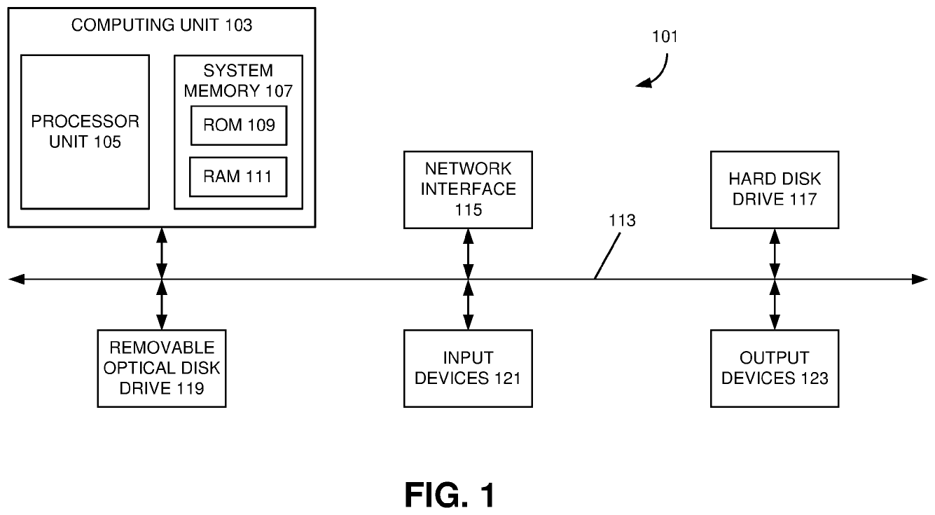

Various examples may be implemented through the execution of software instructions by a computing device 101, such as a programmable computer. Accordingly, FIG. 1 shows an illustrative example of a computing device 101. As seen in this figure, the computing device 101 includes a computing unit 103 with a processor unit 105 and a system memory 107. The processor unit 105 may be any type of programmable electronic device for executing software instructions, but will conventionally be a microprocessor. The system memory 107 may include both a read-only memory (ROM) 109 and a random access memory (RAM) 111. As will be appreciated by those of ordinary skill in the art, both the read-only memory (ROM) 109 and the random access memory (RAM) 111 may store software instructions for execution by the processor unit 105.

The processor unit 105 and the system memory 107 are connected, either directly or indirectly, through a bus 113 or alternate communication structure, to one or more peripheral devices 115-123. For example, the processor unit 105 or the system memory 107 may be directly or indirectly connected to one or more additional memory storage devices, such as a hard disk drive 117, which can be magnetic and/or removable, a removable optical disk drive 119, and/or a flash memory card. The processor unit 105 and the system memory 107 also may be directly or indirectly connected to one or more input devices 121 and one or more output devices 123. The input devices 121 may include, for example, a keyboard, a pointing device (such as a mouse, touchpad, stylus, trackball, or joystick), a scanner, a camera, and a microphone. The output devices 123 may include, for example, a monitor display, a printer and speakers. With various examples of the computing device 101, one or more of the peripheral devices 115-123 may be internally housed with the computing unit 103. Alternately, one or more of the peripheral devices 115-123 may be external to the housing for the computing unit 103 and connected to the bus 113 through, for example, a Universal Serial Bus (USB) connection.

With some implementations, the computing unit 103 may be directly or indirectly connected to a network interface 115 for communicating with other devices making up a network. The network interface 115 can translate data and control signals from the computing unit 103 into network messages according to one or more communication protocols, such as the transmission control protocol (TCP) and the Internet protocol (IP). Also, the network interface 115 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computing device 101 is illustrated as an example only, and it not intended to be limiting. Various embodiments may be implemented using one or more computing devices that include the components of the computing device 101 illustrated in FIG. 1, which include only a subset of the components illustrated in FIG. 1, or which include an alternate combination of components, including components that are not shown in FIG. 1. For example, various embodiments may be implemented using a multi-processor computer, a plurality of single and/or multiprocessor computers arranged into a network, or some combination of both.

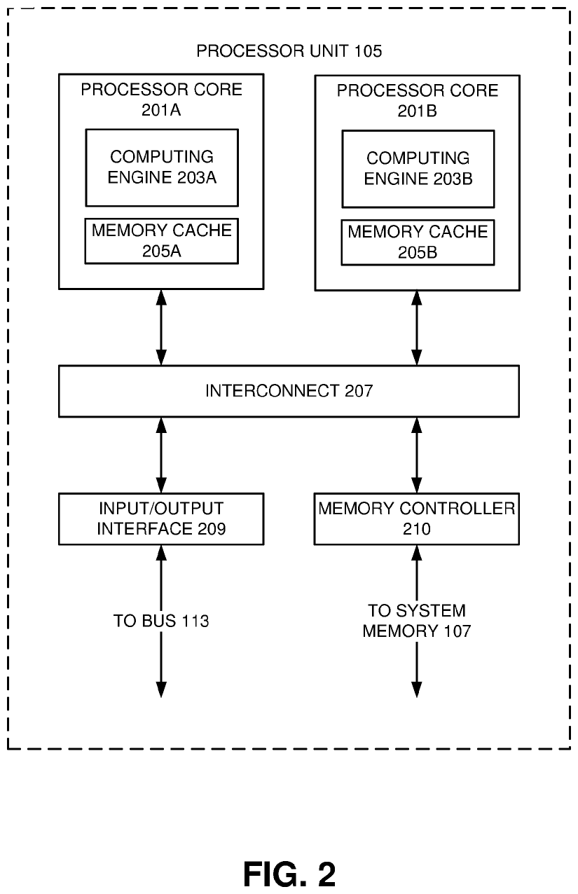

With some implementations, the processor unit 105 can have more than one processor core. Accordingly, FIG. 2 illustrates an example of a multi-core processor unit 105 that may be employed with various embodiments. As seen in this figure, the processor unit 105 includes a plurality of processor cores 201A and 201B. Each processor core 201A and 201B includes a computing engine 203A and 203B, respectively, and a memory cache 205A and 205B, respectively. As known to those of ordinary skill in the art, a computing engine 203A and 203B can include logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203A and 203B may then use its corresponding memory cache 205A and 205B, respectively, to quickly store and retrieve data and/or instructions for execution.

Each processor core 201A and 201B is connected to an interconnect 207. The particular construction of the interconnect 207 may vary depending upon the architecture of the processor unit 105. With some processor cores 201A and 201B, such as the Cell microprocessor created by Sony Corporation, Toshiba Corporation and IBM Corporation, the interconnect 207 may be implemented as an interconnect bus. With other processor units 201A and 201B, however, such as the Opteron™ and Athlon™ dual-core processors available from Advanced Micro Devices of Sunnyvale, California, the interconnect 207 may be implemented as a system request interface device. In any case, the processor cores 201A and 201B communicate through the interconnect 207 with an input/output interface 209 and a memory controller 210. The input/output interface 209 provides a communication interface to the bus 113. Similarly, the memory controller 210 controls the exchange of information to the system memory 107. With some implementations, the processor unit 105 may include additional components, such as a high-level cache memory accessible shared by the processor cores 201A and 201B. It also should be appreciated that the description of the computer network illustrated in FIG. 1 and FIG. 2 is provided as an example only, and is not intended to suggest any limitation as to the scope of use or functionality of alternate embodiments.

### Characterization of Lithographic Process Variation for Manufacturing Process Calibration

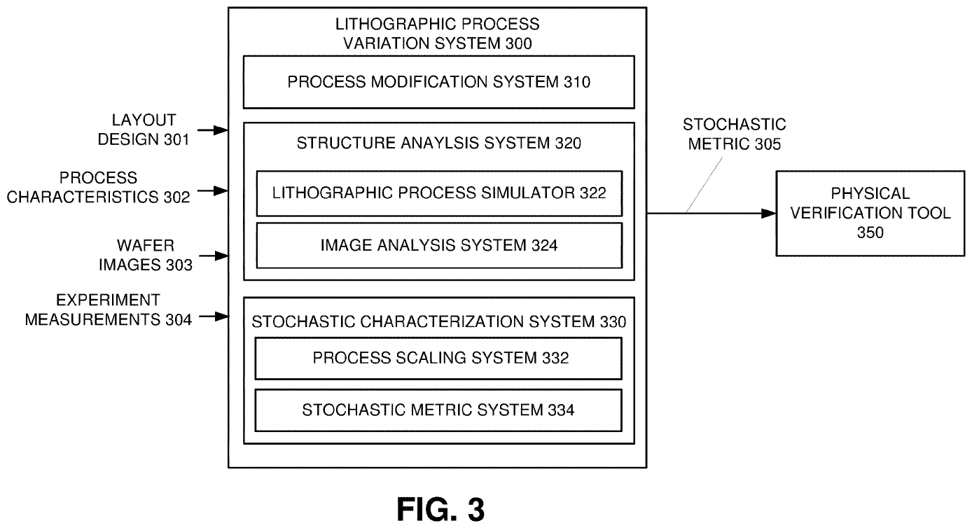

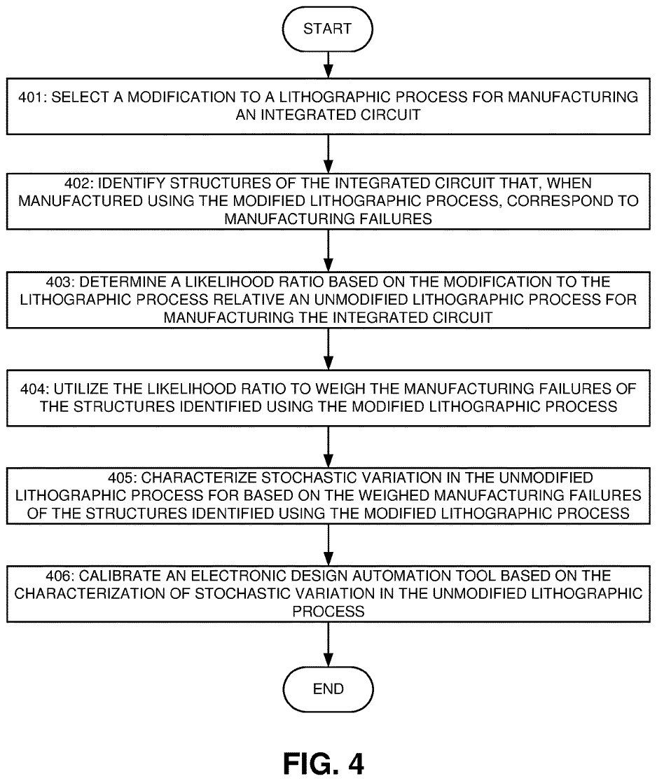

FIG. 3 illustrates an example electronic design automation system with a lithographic process variation system 300 for stochastic variation characterization that may be implemented according to various embodiments. FIG. 4 illustrates an example flowchart for stochastic variation characterization using importance sampling techniques that may be implemented according to various embodiments. Referring to FIGS. 3 and 4, the lithographic process variation system 300 can receive a layout design 301 describing an electronic system, such as an integrated circuit. The layout design 301 can define geometrical information capable of being utilized to manufacture the integrated circuit, which can be specified in a Graphic Data System II (GDSII) format, an Open Access format, a Milkyway format, an EDDM format, an Open Artwork System Interchange Standard (OASIS) format, or the like. The lithographic process variation system 300 also can receive process characteristics 302 that describe various parameters of a manufacturing process, such as a type of resist material, an absorption coefficient of the resist material, an intensity of the emitted light, an exposure dose of the emitted light, a focus of the emitted light on a substrate, or the like, to fabricate the integrated circuit described in the layout design 301.

In some embodiments, the lithographic process variation system 300 can receive information corresponding to experimental manufacture of at least a portion of the integrated circuit described by the layout design 301. For example, the lithographic process variation system 300 can obtain multiple wafer images 303 depicting a portion of an electronic device having physical structures manufactured using one or more lithographic masks associated with the layout design 301 describing the electronic design. In some embodiments, the wafer images 303 can be generated by a scanning electron microscope (SEM) system that can be utilized to collect measurements during optical lithographic experiments for different features on a wafer, for example, performed by a foundry at a manufacturing process node. The lithographic process variation system 300 can receive experiment measurements 304, which can include a number of photons absorbed by photoresist during the experimental manufacture of at least a portion of the integrated circuit described by the layout design 301.

The lithographic process variation system 300 can include a process modification system 310 to determine stochastic variation in a lithographic process described by the process characteristics 302 would result in a low number of integrated circuit structure failures or have a low failure probability. In a block 401 of FIG. 4, the process modification system 310 can select a modification to the lithographic process for manufacturing the integrated circuit. The modification to the lithographic process, in some embodiments, can alter one or more of the parameters of the manufacturing process in an attempt to increase a number of integrated circuit structure failures due to stochastic variation in the modified lithographic process relative to the lithographic process described by the process characteristics 302. As will be described below in greater detail, by attempting to increase the number of integrated circuit structure failures, the lithographic process variation system 300 can identify integrated circuit structure failures due to stochastic variation more often, which can be used to reduce a number of simulation trials or experimental trials that would be performed on the modified lithographic process to determine an accurate impact of the stochastic variation for the unmodified lithographic process described in the process characteristics 302.

The lithographic process variation system 300 can include a structure analysis system 320 that, in a block 402 of FIG. 4, can identify structures of the integrated circuit that, when manufactured using the modified lithographic process, correspond to manufacturing failures. The structure analysis system 320, either through lithographic simulation or through wafer image analysis of experimental manufacturing, can utilize multiple trials to identify physical dimensions of the structures using the modified lithographic process. In some embodiments, the structure analysis system 320 can compare the physical dimensions of the structures relative to expected dimensions and expected separation between structures, for example, from the layout design 301, to determine whether stochastic variation has rendered the physical dimensions of the structures as corresponding to manufacturing failures. For instance, when attempting to ascertain whether a structure has a pinching-type manufacturing failure, the structure analysis system 320 can compare the physical dimensions of the structures along an expected gauge for the structure to determine whether the line edges of the structure deviate from the expected gauge in a way that annunciates a pinching-type manufacturing failure.

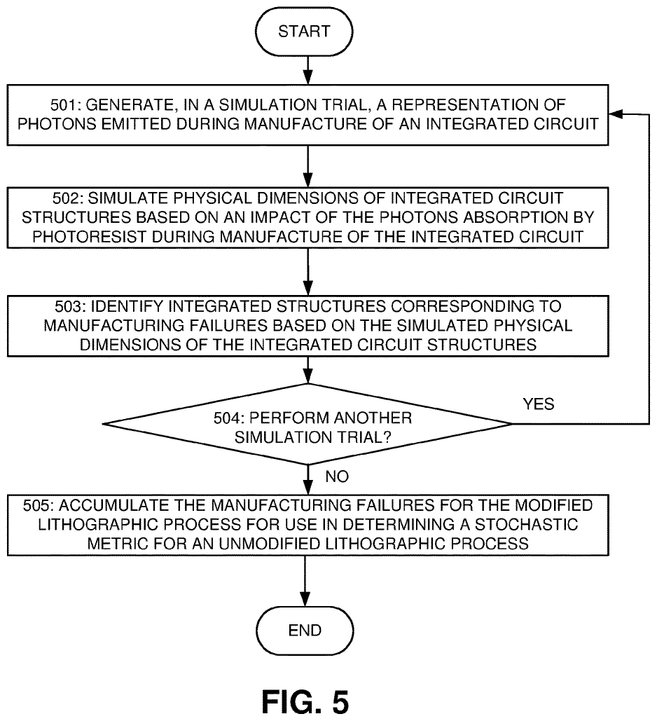

The structure analysis system 320 can include a lithographic process simulator 322 to simulate the manufacture of the integrated circuit using the modified lithographic process and then identify structures of the simulated integrated circuit that correspond to manufacturing failures. Embodiments of the lithographic process simulation will be described in greater detail below with reference to FIG. 5.

FIG. 5 illustrates an example flowchart for identifying integrated circuit structure failures through simulation that may be implemented according to various embodiments. Referring to FIG. 5, a computing system implementing a structure analysis system can, in a block 501, generate, in a simulation trial, a representation of photons emitted during manufacture of an integrated circuit. In some embodiments, the structure analysis system can utilize the characteristics of the modified lithographic process to simulate a number of photons to be absorbed by photoresist during the simulation trial and also to simulate the coordinate locations where the photoresist absorbs each of the photons. In some embodiments, the structure analysis system can determine the number of photons to be absorbed by photoresist during the simulation trial utilizing a Monte Carlo simulation over a Poisson distribution with a known mean of absorbed photons for the modified lithographic process. The structure analysis system also can determine the coordinate locations where the photoresist absorbs each of the photons utilizing a Monte Carlo simulation over a probability density function characterizing the modified lithographic process with known process parameters, such as an absorption coefficient of the photoresist, an intensity of the emitted light, or the like.

In a block 502, the structure analysis system can simulate physical dimensions of integrated circuit structures based on an impact of the photons absorption by photoresist during manufacture of the integrated circuit. Since each photon absorbed by the photoresist can contribute to a localized deprotection of the photoresist, for example, in a random Gaussian field, centered around to the coordinates associated with the absorption, the structure analysis system can utilize the number of absorbed photons and their corresponding coordinates to determine the impact that each absorbed photon has on the photoresist and accumulate the impacts to indicate an overall level of deprotection in the photoresist. If the overall level of deprotection exceeds a threshold level specific to the photoresist, then during a development process, the photoresist will be removed from those locations. If the overall level of deprotection falls below a threshold level specific to the photoresist, then during a development process, the photoresist will be retained from those locations. The delineation between retained and removed photoresist in the simulated development process can define the physical dimensions for the integrated circuit structures.

In a block 503, the structure analysis system can identify integrated structures corresponding to manufacturing failures based on the simulated physical dimensions of the integrated circuit structures. In some embodiments, the structure analysis system can utilize the layout design for the integrated circuit or gauges associated with expected structures to determine expected physical dimensions of the structures and identify when the simulated physical dimensions of the integrated circuit structures deviate from the expected physical dimensions of the structures sufficiently to constitute a manufacturing failure.

In a block 504, the structure analysis system can determine whether to perform another simulation trial for the manufacture of the integrated circuit. In some embodiments, the decision to perform additional trials may correspond to a predetermined number of trials, the identification of manufacturing failures, or the like. When, in the block 504, the structure analysis system determines to perform another simulation trial for the manufacture of the integrated circuit, execution can return to the block 501, where structure analysis system can generate a different representation of photons emitted during manufacture of an integrated circuit and simulate physical dimensions of integrated circuit structures using the generated representation of the photons.

When, in the block 504, the structure analysis system, determines not to perform another simulation trial for the manufacture of the integrated circuit, execution can proceed to a block 505, where the structure analysis system can accumulate the manufacturing failures for the modified lithographic process for use in determining a stochastic metric for an unmodified lithographic process. As will be described below in greater detail, in some embodiments, during the accumulation process, the manufacturing failures for the modified lithographic process may be weighed or scaled, for example, by a likelihood ratio that correlates the modified lithographic process to the unmodified lithographic process.

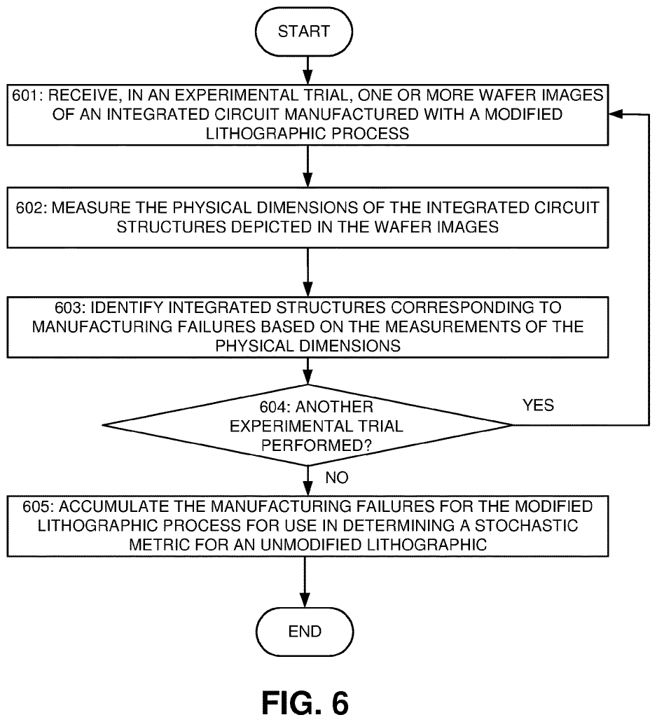

Referring back to FIGS. 3 and 4, the structure analysis system 320 can include an image analysis system 324 to use the wafer images 303 to measure physical dimensions of integrated circuit structures manufactured the modified lithographic process and then identify which of the structures, if any, correspond to manufacturing failures. Embodiments of the identifying failed structures from wafer images associated with experimental integrated circuit manufacturing will be described in greater detail below with reference to FIG. 6.

FIG. 6 illustrate examples of identifying integrated circuit structure failures through image analysis of manufactured integrated circuit structures according to various examples. Referring to FIG. 6, a computing system implementing a structure analysis system can, in a block 601, receive, in an experimental trial, one or more wafer images of an integrated circuit manufactured with a modified lithographic process. In some embodiments, the wafer images can depict a portion of an electronic device having physical structures manufactured using one or more lithographic masks associated with the layout design describing the electronic design. In some embodiments, the wafer images can be generated by a scanning electron microscope (SEM) system that can be utilized to collect measurements during optical lithographic experiments for different features on a wafer.

In a block 602, the structure analysis system can measure the physical dimensions of the integrated circuit structures depicted in the wafer images. In some embodiments, the structure analysis system can perform image analysis on the wafer images to identify line edges of the integrated circuit structures and then utilize the line edges to measure the physical dimensions of the integrated circuit structures.

In a block 603, the structure analysis system can identify integrated circuit structures corresponding to manufacturing failures based on the measurements of the physical dimensions. In some embodiments, the structure analysis system can utilize the layout design for the integrated circuit or gauges associated with expected structures to determine expected physical dimensions of the structures and identify when the simulated physical dimensions of the integrated circuit structures deviate from the expected physical dimensions of the structures sufficiently to constitute a manufacturing failure.

In a block 604, the structure analysis system can determine whether another experimental trial had been performed. When, in the block 604, the structure analysis system determines to another experimental trial had been performed, execution can return to the block 601, where the structure analysis system can receive, in a different experimental trial, one or more images of a manufactured integrated circuit.

When, in the block 604, the structure analysis system determines to another experimental trial had been performed, execution can proceed to the block 605, where the structure analysis system can accumulate the manufacturing failures for the modified lithographic process for use in determining a stochastic metric for an unmodified lithographic process. As will be described below in greater detail, in some embodiments, during the accumulation process, the manufacturing failures for the modified lithographic process may be weighed or scaled, for example, by a likelihood ratio that correlates the modified lithographic process to the unmodified lithographic process.

Referring back to FIGS. 3 and 4, the lithographic process variation system 300 can include a stochastic characterization system 330 to utilize the manufacturing failures caused by stochastic variation in the modified lithographic process to determine at least one stochastic metric 305 associated with the unmodified lithographic process described in the process characteristics 302. In some embodiments, the stochastic metric 305 can correspond to an estimate of failure probability associated with stochastic variation using the unmodified lithographic process. The stochastic metric 305 also can describe other quantities, such as line edge roughness, line width roughness, local critical dimension (CD) non-uniformity, or the like.

The stochastic characterization system 330 can include a process scaling system 332, in a block 403 of FIG. 4, to determine a likelihood ratio based on the modification to the lithographic process relative an unmodified lithographic process for manufacturing the integrated circuit. The likelihood ratio can be a numerical factor relating the modified lithographic process and the unmodified lithographic process, which can be utilized to scale the manufacturing failures identified in trials using the modified lithographic process in order to characterize the stochastic variation associated with the unmodified lithographic process. In some embodiments, the likelihood ratio can be expressed as a ratio of probability density functions probability density function characterizing the unmodified lithographic process relative to the modified lithographic process using known process parameters, such as an absorption coefficient of the photoresist, an intensity of the emitted light, or the like. In some embodiments, the ratio of the probability density functions used for the likelihood ratio is shown in Equation 1.

$$\frac{{f}_{P} ( Q )}{{f}_{Q} ( Q )} = {( \frac{\overline{{N}_{hv}^{( P )}}}{\overline{{N}_{hv}^{( Q )}}} )}^{{N}_{hv}} exp ( \overline{{N}_{hv}^{( Q )}} - \overline{{N}_{hv}^{( P )}} ) \qquad Equation 1$$

In Equation 1, the likelihood ratio corresponds to a probability density function for the unmodified lithographic process f_{P}(Q) divided by a probability density function for the modified lithographic process f_{Q}(Q). The likelihood ratio also corresponds to a ratio of an average number of photons absorbed using the unmodified lithographic process,

$$\overline{{N}_{hv}^{( P )}} ,$$

divided by an average number of photons absorbed using the modified lithographic process,

$$\overline{{N}_{hv}^{( Q )}} ,$$

raised to the power of a number of photons absorbed during an individual trial using the modified lithographic process, which is multiplied by the exponential function having an exponent corresponding to the average number of photons absorbed using the modified lithographic process,

$$\overline{{N}_{hv}^{( Q )}} ,$$

minus the average number of photons absorbed using the unmodified lithographic process,

$$\overline{{N}_{hv}^{( P )}} .$$

The process scaling system 332 can determine the likelihood ratio for each simulation trial or experimental performed by the structure analysis system 320 using know average number of photons absorbed using the modified and unmodified lithographic processes and the individual number of photons absorbed during each trial using the modified lithographic process.

In a block 404, the lithographic process variation system 300 can utilize the likelihood ratio determined by the process scaling system 332 to weigh the manufacturing failures of the identified structures manufactured using the modified lithographic process determined by the structure analysis system 320. In some embodiments, the structure analysis system 320, during an accumulation of the manufacturing failures, can scale each of the identified manufacturing failures in a trial by the likelihood ratio for that trial, which can convert a set of accumulated failures for the modified lithographic process into a set of accumulated failures for the unmodified lithographic process.

The stochastic characterization system 330 can include a stochastic metric system 334, in a block 405 of FIG. 4, to characterize stochastic variation in the unmodified lithographic process for manufacturing the integrated circuit based on the weighed manufacturing failures of the identified structures. In some embodiments, the stochastic metric system 334 can utilize the weighed manufacturing failures of the identified structures as an estimate of failure probability for the unmodified lithographic process. The stochastic metric system 334 also can utilize the physical dimensions of the structures determined in the structure analysis system 320 to determine a line edge roughness or variation in an edge of a structure, determine a line width roughness or a variation in a width of a structure between line edges, a local critical dimension (CD) non-uniformity or a variability in a diameter associated with a structure, or the like. The lithographic process variation system 300 can output the estimate of failure probability for the unmodified lithographic process, line edge roughness, line width roughness, local critical dimension (CD) non-uniformity, or the like, as a stochastic metric 305 that characterizes an impact of stochastic variability on manufactured structures using the unmodified lithographic process.

In some embodiments, the lithographic process variation system 300 can output the stochastic metric 305 to a physical verification tool 350 in the electronic design automation system. In a block 406 of FIG. 4, the physical verification tool 350 or other electronic design automation tool can use the stochastic metric 305 during an internal calibration process or to iterate on modifications to the layout design 301 or a mask design for manufacturing of the integrated circuit described in the layout design 301. For example, when the physical verification tool 350 corresponds to an optical proximity correction (OPC) tool of a source mask optimization (SMO) tool, the physical verification tool 350 can alter a mask design corresponding to one or more structures described in a layout design 301 and utilize the stochastic metric 305 to determine whether the alteration of the mask design increased or decreased the estimate of failure probability for manufacturing the integrated circuit using the unmodified lithographic process.

The system and apparatus described above may use dedicated processor systems, micro controllers, programmable logic devices, microprocessors, or any combination thereof, to perform some or all of the operations described herein. Some of the operations described above may be implemented in software and other operations may be implemented in hardware. Any of the operations, processes, and/or methods described herein may be performed by an apparatus, a device, and/or a system substantially similar to those as described herein and with reference to the illustrated figures.

The processing device may execute instructions or “code” stored in memory. The memory may store data as well. The processing device may include, but may not be limited to, an analog processor, a digital processor, a microprocessor, a multi-core processor, a processor array, a network processor, or the like. The processing device may be part of an integrated control system or system manager, or may be provided as a portable electronic device configured to interface with a networked system either locally or remotely via wireless transmission.

The processor memory may be integrated together with the processing device, for example RAM or FLASH memory disposed within an integrated circuit microprocessor or the like. In other examples, the memory may comprise an independent device, such as an external disk drive, a storage array, a portable FLASH key fob, or the like. The memory and processing device may be operatively coupled together, or in communication with each other, for example by an I/O port, a network connection, or the like, and the processing device may read a file stored on the memory. Associated memory may be “read only” by design (ROM) by virtue of permission settings, or not. Other examples of memory may include, but may not be limited to, WORM, EPROM, EEPROM, FLASH, or the like, which may be implemented in solid state semiconductor devices. Other memories may comprise moving parts, such as a known rotating disk drive. All such memories may be “machine-readable” and may be readable by a processing device.

Operating instructions or commands may be implemented or embodied in tangible forms of stored computer software (also known as “computer program” or “code”). Programs, or code, may be stored in a digital memory and may be read by the processing device. “Computer-readable storage medium” (or alternatively, “machine-readable storage medium”) may include all of the foregoing types of memory, as well as new technologies of the future, as long as the memory may be capable of storing digital information in the nature of a computer program or other data, at least temporarily, and as long at the stored information may be “read” by an appropriate processing device. The term “computer-readable” may not be limited to the historical usage of “computer” to imply a complete mainframe, mini-computer, desktop or even laptop computer. Rather, “computer-readable” may comprise storage medium that may be readable by a processor, a processing device, or any computing system. Such media may be any available media that may be locally and/or remotely accessible by a computer or a processor, and may include volatile and non-volatile media, and removable and non-removable media, or any combination thereof.

A program stored in a computer-readable storage medium may comprise a computer program product. For example, a storage medium may be used as a convenient means to store or transport a computer program. For the sake of convenience, the operations may be described as various interconnected or coupled functional blocks or diagrams. However, there may be cases where these functional blocks or diagrams may be equivalently aggregated into a single logic device, program or operation with unclear boundaries.

### Conclusion

While the application describes specific examples of carrying out embodiments of the invention, those skilled in the art will appreciate that there are numerous variations and permutations of the above described systems and techniques that fall within the spirit and scope of the invention as set forth in the appended claims. For example, while specific terminology has been employed above to refer to design processes, it should be appreciated that various examples of the invention may be implemented using any desired combination of electronic design automation processes.

One of skill in the art will also recognize that the concepts taught herein can be tailored to a particular application in many other ways. In particular, those skilled in the art will recognize that the illustrated examples are but one of many alternative implementations that will become apparent upon reading this disclosure.

Although the specification may refer to “an”, “one”, “another”, or “some” example(s) in several locations, this does not necessarily mean that each such reference is to the same example(s), or that the feature only applies to a single example.

Various specific methods to modify the lithographic process in order to practice this invention can be used, such as when failure probability of an original lithographic process is too low to be estimated by performing repeated randomized trials in computational simulations or to be measured by experimentally measuring multiple independently patterned instances of identical features. Such situation can occur, for instance, when the expected failure probability has the order of 1 in 10 billion, since it may be impractical or not realistic to perform 10 billion or more randomized simulations of any reasonable scale or to perform experimental measurements on 10 billion or more identical patterned features. A modification of the lithographic process can then be considered. Such modification can ensure that the probability of failure increases becoming, for instance, of the order of one failure in 1 million. Such modification can be achieved, for instance, by modifying the dose, focus, mask shape, deprotection threshold, exposure film stack, or the like in simulations. In the case of experimental measurements, modification of dose and focus can also be implemented. The effect of modification of the deprotection threshold can be achieved by modifying the development time or other parameters of the development process or by performing a “flood” exposure of the photoresist with a uniform light intensity (in any reasonable wavelength) before or after performing the patterning exposure in the wavelength used in the lithographic process. While the above examples deal with the assessment of the failure probability, the same modifications can be used to facilitate the assessment of any other stochastic metric. For instance, the metrics dealing with the edge roughness of the patterned features (line edge roughness, line width roughness or local CD non-uniformity) may become challenging to experimental measurements when the roughness becomes too small to be measured accurately by available experimental methods. Practicing the methods described above can allow modification to the lithographic process so that the edge roughness increases into the range, where it can be measured more accurately. The importance sampling methods can then be used to convert the roughness measured in the modified process into the roughness of the original process, which can otherwise be challenging to measure directly.

1. A method comprising:
selecting, by a computing system, a modification to a lithographic process for manufacturing an integrated circuit;
identifying, by the computing system, structures of the integrated circuit that, when manufactured using the modified lithographic process, correspond to manufacturing failures;
determining, by the computing system, a likelihood ratio based, at least in part, on the modification to the lithographic process relative an unmodified lithographic process for manufacturing the integrated circuit; and
utilizing, by the computing system, the likelihood ratio to weigh the manufacturing failures of the identified structures manufactured using the modified lithographic process to characterize stochastic variation in the unmodified lithographic process for manufacturing the integrated circuit.

2. The method of claim 1, further comprising utilizing, by the computing system, the characterization of stochastic variation in the unmodified lithographic process to calibrate an electronic design automation tool configured to modify a layout design for the integrated circuit or a mask design for manufacturing of the integrated circuit.

3. The method of claim 1, further comprising simulating, by the computing system, the manufacture of the integrated circuit using the modified lithographic process, wherein identifying the structures of the integrated circuit that correspond to manufacturing failures is based on the simulated manufacture of the integrated circuit.

4. The method of claim 3, wherein simulating the manufacture of the integrated circuit using the modified lithographic process further comprises:
simulating photons absorbed by photoresist during the manufacturing of the integrated circuit using the modified lithographic process; and
accumulating an impact of the photons on the photoresist to determine physical dimensions of structures developed based on the photoresist having absorbed the simulated photons during the simulated manufacture of the integrated circuit.

5. The method of claim 1, wherein identifying the structures of the integrated circuit that correspond to manufacturing failures further comprises:
measuring physical dimensions of structures having been manufactured using the modified lithographic process; and
comparing the measured physical dimensions of the structures to predetermine thresholds to identify the structures of the integrated circuit that correspond to manufacturing failures.

6. The method of claim 1, wherein the modification to the lithographic process is configured to alter a number of photons absorbed by photoresist during the manufacturing of the integrated circuit, and wherein determining the likelihood ratio is based, at least in part, on the altered number of the absorbed photons.

7. The method of claim 1, wherein the characterization of stochastic variation in the lithographic process includes at least one of a failure probability metric, a line edge roughness metric, a line width roughness metric, or a local critical dimension non-uniformity metric.

8. An apparatus comprising at least one computer-readable memory device storing instructions configured to cause one or more processing devices to perform operations comprising:
selecting a modification to a lithographic process for manufacturing an integrated circuit;
identifying structures of the integrated circuit that, when manufactured using the modified lithographic process, correspond to manufacturing failures;
determining a likelihood ratio based, at least in part, on the modification to the lithographic process relative an unmodified lithographic process for manufacturing the integrated circuit; and
utilizing the likelihood ratio to weigh the manufacturing failures of the identified structures manufactured using the modified lithographic process to characterize stochastic variation in the unmodified lithographic process for manufacturing the integrated circuit.

9. The apparatus of claim 8, wherein the instructions are configured to cause one or more processing devices to perform operations further comprising utilizing the characterization of stochastic variation in the unmodified lithographic process to calibrate an electronic design automation tool configured to modify a layout design for the integrated circuit or a mask design for manufacturing of the integrated circuit.

10. The apparatus of claim 8, wherein the instructions are configured to cause one or more processing devices to perform operations further comprising simulating the manufacture of the integrated circuit using the modified lithographic process, wherein identifying the structures of the integrated circuit that correspond to manufacturing failures is based on the simulated manufacture of the integrated circuit.

11. The apparatus of claim 10, wherein simulating the manufacture of the integrated circuit using the modified lithographic process further comprises:
simulating photons absorbed by photoresist during the manufacturing of the integrated circuit using the modified lithographic process; and
accumulating an impact of the photons on the photoresist to determine physical dimensions of structures developed based on the photoresist having absorbed the simulated photons during the simulated manufacture of the integrated circuit.

12. The apparatus of claim 8, wherein identifying the structures of the integrated circuit that correspond to manufacturing failures further comprises:
measuring physical dimensions of structures having been manufactured using the modified lithographic process; and
comparing the measured physical dimensions of the structures to predetermine thresholds to identify the structures of the integrated circuit that correspond to manufacturing failures.

13. The apparatus of claim 8, wherein the modification to the lithographic process is configured to alter a number of photons absorbed by photoresist during the manufacturing of the integrated circuit, and wherein determining the likelihood ratio is based, at least in part, on the altered number of the absorbed photons.

14. The apparatus of claim 8, wherein the characterization of stochastic variation in the lithographic process includes at least one of a failure probability metric, a line edge roughness metric, a line width roughness metric, or a local critical dimension non-uniformity metric.

15. A system comprising:
a memory system configured to store computer-executable instructions; and
a computing system, in response to execution of the computer-executable instructions, is configured to:
select a modification to a lithographic process for manufacturing an integrated circuit;
identify structures of the integrated circuit that, when manufactured using the modified lithographic process, correspond to manufacturing failures;
determine a likelihood ratio based, at least in part, on the modification to the lithographic process relative an unmodified lithographic process for manufacturing the integrated circuit; and
utilize the likelihood ratio to weigh the manufacturing failures of the identified structures manufactured using the modified lithographic process to characterize stochastic variation in the unmodified lithographic process for manufacturing the integrated circuit.

16. The system of claim 15, wherein the computing system, in response to execution of the computer-executable instructions, is further configured to utilize the characterization of stochastic variation in the unmodified lithographic process to calibrate an electronic design automation tool configured to modify a layout design for the integrated circuit or a mask design for manufacturing of the integrated circuit.

17. The system of claim 15, wherein the computing system, in response to execution of the computer-executable instructions, is further configured to simulate the manufacture of the integrated circuit using the modified lithographic process, wherein identifying the structures of the integrated circuit that correspond to manufacturing failures is based on the simulated manufacture of the integrated circuit.

18. The system of claim 17, wherein the computing system, in response to execution of the computer-executable instructions, is further configured to simulate the manufacture of the integrated circuit using the modified lithographic process by:
simulating photons absorbed by photoresist during the manufacturing of the integrated circuit using the modified lithographic process; and
accumulating an impact of the photons on the photoresist to determine physical dimensions of structures developed based on the photoresist having absorbed the simulated photons during the simulated manufacture of the integrated circuit.

19. The system of claim 15, wherein the computing system, in response to execution of the computer-executable instructions, is further configured to identify the structures of the integrated circuit that correspond to manufacturing failures by:
measuring physical dimensions of structures having been manufactured using the modified lithographic process; and
comparing the measured physical dimensions of the structures to predetermine thresholds to identify the structures of the integrated circuit that correspond to manufacturing failures.

20. The system of claim 15, wherein the modification to the lithographic process is configured to alter a number of photons absorbed by photoresist during the manufacturing of the integrated circuit, and wherein determining the likelihood ratio is based, at least in part, on the altered number of the absorbed photons.
